(19) United States
(12) Patent Application Publication
(10) Pub. No.: US 2023/0135461 A1
(43) Pub. Date: May 4, 2023

(54) SEMICONDUCTOR DEVICE

(71) Applicant: Mitsubishi Electric Corporation, Tokyo (JP)

(72) Inventors: Keisuke AOKI, Tokyo (JP); Tomohisa YAMANE, Tokyo (JP); Katsuhisa KODAMA, Tokyo (JP); Yo TANAKA, Tokyo (JP); Masakazu TANI, Tokyo (JP)

(73) Assignee: Mitsubishi Electric Corporation, Tokyo (JP)

(21) Appl. No.: 17/862,607

(22) Filed: Jul. 12, 2022

(30) Foreign Application Priority Data
Nov. 2, 2021 (JP) 2021-179155

(51) Int. Cl. H01L 25/18; H01L 25/07; H01L 23/00; H01L 23/46

(52) U.S. Cl. CPC H01L 25/18; H01L 25/072; H01L 24/40; H01L 23/46; H01L 23/3735

(57) ABSTRACT

The semiconductor device includes: a heat spreader; a plurality of semiconductor elements; and one or a plurality of temperature detection elements. If a line segment connecting centers of two respective adjacent ones of the semiconductor elements is defined as X, a straight line that passes through one of the centers of the two adjacent semiconductor elements and that is perpendicular to X and parallel to the one-side surface of the heat spreader is defined as Y1, and a straight line that passes through another one of the centers of the two adjacent semiconductor elements and that is perpendicular to X and parallel to the one-side surface of the heat spreader is defined as Y2, at least a part of the temperature detection element is located in an arrangement region interposed between Y1 and Y2, as seen in a direction perpendicular to the one-side surface of the heat spreader.

### BACKGROUND OF THE INVENTION

### 1. Field of the Invention

The present disclosure relates to a semiconductor device.

### 2. Description of the Background Art

An electrically-driven vehicle such as an electric automobile or a plug-in hybrid automobile is provided with semiconductor devices for converting power from a high-voltage battery. Each semiconductor device is composed of a plurality of semiconductor elements such that a bridge circuit is formed. The semiconductor device converts, into AC power, DC power supplied from the battery in order to drive a motor. A semiconductor device including a circuit for converting DC power into AC power by appropriately operating semiconductor elements to be turned on or off, is called an inverter device. In such an inverter device, power transistors, IGBTs, FETs, and the like are widely used as the semiconductor elements serving as switching elements composing a bridge circuit. Further, inverter devices having a module structure in which a plurality of these semiconductor elements are mounted and made into one package, are widely used.

In the case of driving a motor of a motorized vehicle, high voltage is applied to and high current flows to the plurality of semiconductor elements in the module structure so that the semiconductor elements generate heat. The heat generation might cause fracture of the semiconductor elements. It is important to ascertain the temperature of each semiconductor element in order to protect the semiconductor element from fracture of the semiconductor element due to heat generation.

A configuration has been disclosed in which a temperature detection element is provided inside a semiconductor device in order to ascertain the temperature of a semiconductor element (see, for example, Patent Document 1). In the disclosed semiconductor device, the semiconductor element and the temperature detection element are apart from each other and mounted on an insulation layer. To each of a plurality of the semiconductor elements, a corresponding temperature detection element is provided at a position corresponding to the semiconductor element, and each of a plurality of the temperature detection elements detects the temperature of the corresponding semiconductor element.
Patent Document 1: Japanese Laid-Open Patent Publication No. 2021-86933

In the structure of the semiconductor device in the above Patent Document 1, the temperature of each semiconductor element can be detected by the corresponding one of the plurality of temperature detection elements for protection from overheating. However, the semiconductor element and the temperature detection element are disposed on the insulation layer, and the semiconductor element and the temperature detection element are thermally connected to each other via the insulation layer. Thus, the thermal resistance between the semiconductor element and the temperature detection element is high, and a response by the temperature detection element might be delayed relative to increase in the temperature of the semiconductor element due to heat generation. Therefore, a drawback arises in that the temperature of the semiconductor element cannot be accurately detected.

In addition, the temperature detection elements are individually provided correspondingly to the plurality of semiconductor elements, and thus the number of control terminals and a space for wiring to the control terminals increase. Therefore, a drawback arises in that the semiconductor device is upsized.

### SUMMARY OF THE INVENTION

Considering this, an object of the present disclosure is to provide a downsized semiconductor device in which the accuracy of detecting the temperature of a semiconductor element is improved.

A semiconductor device according to the present disclosure includes: a heat spreader formed in a plate shape; a plurality of semiconductor elements connected to a one-side surface of the heat spreader; and one or a plurality of temperature detection elements. Each temperature detection element is provided on the one-side surface of the heat spreader or inside any of the semiconductor elements. If a line segment connecting centers of two respective adjacent ones of the semiconductor elements is defined as X, a straight line that passes through one of the centers of the two adjacent semiconductor elements and that is perpendicular to X and parallel to the one-side surface of the heat spreader is defined as Y1, and a straight line that passes through another one of the centers of the two adjacent semiconductor elements and that is perpendicular to X and parallel to the one-side surface of the heat spreader is defined as Y2, at least a part of the temperature detection element is located in an arrangement region interposed between Y1 and Y2, as seen in a direction perpendicular to the one-side surface of the heat spreader.

In the semiconductor device according to the present disclosure: each temperature detection element is provided on the one-side surface of the heat spreader or inside any of the semiconductor elements; and, if a line segment connecting centers of two respective adjacent ones of the semiconductor elements is defined as X, a straight line that passes through one of the centers of the two adjacent semiconductor elements and that is perpendicular to X and parallel to the one-side surface of the heat spreader is defined as Y1, and a straight line that passes through another one of the centers of the two adjacent semiconductor elements and that is perpendicular to X and parallel to the one-side surface of the heat spreader is defined as Y2, at least a part of the temperature detection element is located in an arrangement region interposed between Y1 and Y2, as seen in a direction perpendicular to the one-side surface of the heat spreader. Consequently, the thermal resistances between the semiconductor elements and the temperature detection elements are low, and it is possible to decrease a delay, in a response by each temperature detection element, that occurs relative to increase in the temperatures of the semiconductor elements due to heat generation. Therefore, the accuracy of detecting the temperature of each semiconductor element can be improved. In addition, one of the temperature detection elements can accurately detect the temperatures of at least two of the semiconductor elements, and thus the one temperature detection element enables the at least two semiconductor elements to be protected from overheating. Therefore, the number of the temperature detection elements can be decreased, whereby the semiconductor device can be downsized.

### BRIEF DESCRIPTION OF THE DRAWINGS

FIG. 1 is a diagram showing a circuit configuration of an inverter in which semiconductor devices according to a first embodiment are used;

FIG. 2 is a plan view schematically showing configurations of two of the semiconductor devices according to the first embodiment;

FIG. 3 is a cross-sectional view schematically showing the semiconductor devices, taken at a cross-sectional position A-A in FIG. 2;

FIG. 4 is a cross-sectional view schematically showing a temperature detection element of one of the semiconductor devices according to the first embodiment;

FIG. 5 is a plan view showing a major part of the semiconductor device according to the first embodiment;

FIG. 6 is a plan view schematically showing a configuration of a semiconductor device according to a second embodiment;

FIG. 7 is a plan view schematically showing configurations of semiconductor devices according to a third embodiment;

FIG. 8 is a cross-sectional view schematically showing the semiconductor devices, taken at a cross-sectional position B-B in FIG. 7;

FIG. 9 is a plan view showing a major part of a semiconductor device according to a fourth embodiment; and

FIG. 10 is a side view schematically showing configurations of semiconductor devices according to a fifth embodiment.

### DETAILED DESCRIPTION OF THE PREFERRED

### Embodiments of the Invention

Hereinafter, semiconductor devices according to embodiments of the present disclosure will be described with reference to the drawings. Description will be given while the same or corresponding members and parts in the drawings are denoted by the same reference characters.

### First Embodiment

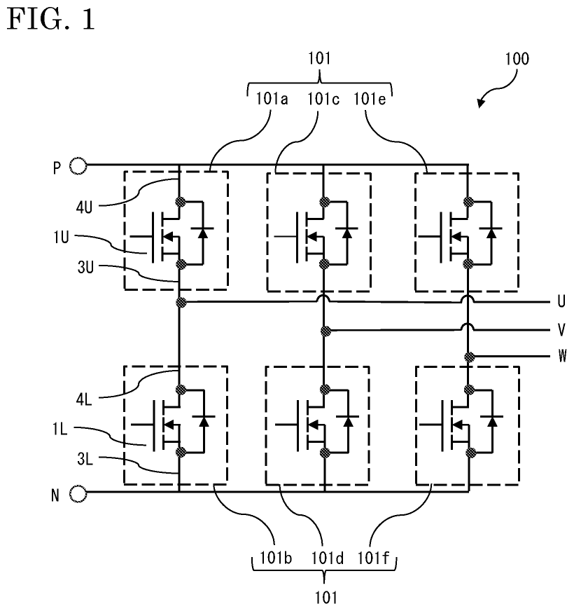

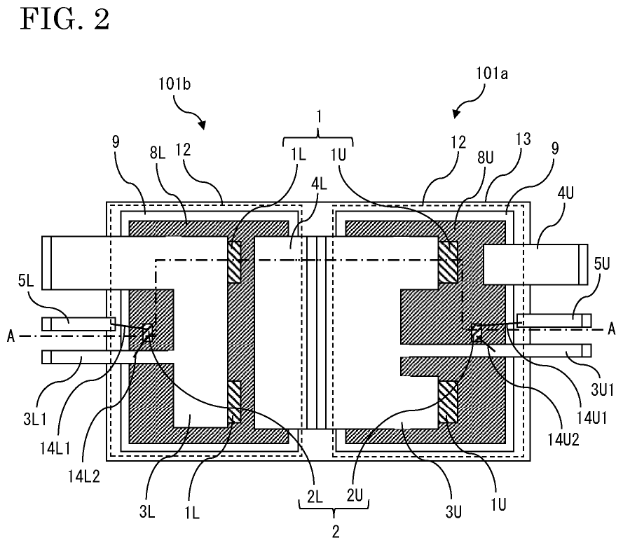

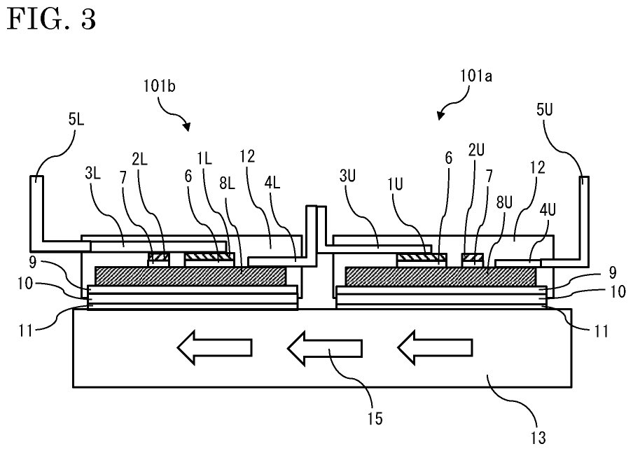

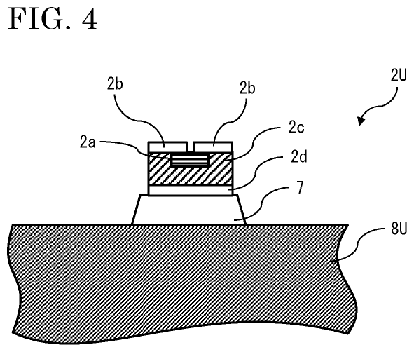

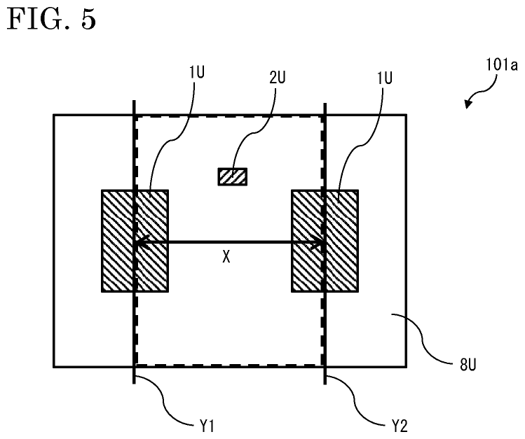

FIG. 1 is a diagram showing a circuit configuration of a main circuit 100 of an inverter in which semiconductor devices 101 according to a first embodiment are used. FIG. 2 is a plan view schematically showing configurations of semiconductor devices 101a and 101b for a U phase. FIG. 3 is a cross-sectional view schematically showing the semiconductor devices 101a and 101b, taken at a cross-sectional position A-A in FIG. 2. FIG. 4 is a cross-sectional view schematically showing a temperature detection element 2U of the semiconductor device 101a. FIG. 5 is a plan view showing a major part of the semiconductor device 101a. In FIG. 2, sealing members 12 have been excluded, and the broken lines indicate the external shapes of the sealing members 12. Each semiconductor device 101 is a device for converting power through switching operations of semiconductor elements 1.

<Main Circuit 100 of Inverter>

The main circuit 100 of the inverter is connected to a battery on the left side of FIG. 1 and connected to a driven motor as a load on the right side of FIG. 1. The main circuit 100 of the inverter converts DC power from the battery into AC power and outputs the AC power. The main circuit 100 of the inverter has six semiconductor devices 101. The main circuit 100 of the inverter is formed by three phases, i.e., the U phase, a V phase, and a W phase. The semiconductor devices 101a and 101b are provided for the U phase, semiconductor devices 101c and 101d are provided for the V phase, and semiconductor devices 101e and 101f are provided for the W phase. Each phase is formed by an upper arm and a lower arm. The semiconductor devices 101a, 101c, and 101e are upper arms, and the semiconductor devices 101b, 101d, and 101f are lower arms. Each semiconductor device 101 includes a temperature detection element 2 (not shown in FIG. 1).

<Semiconductor Devices 101>

The structures of the semiconductor devices 101 are the same among the phases. Thus, the configurations of the semiconductor devices 101 will be described with reference to FIG. 2 and FIG. 3, with the U phase being a representative. In FIG. 2 and FIG. 3, electrodes of semiconductor elements 1 and temperature detection elements 2 are not shown in order to make it easy to understand the configurations. Each of the semiconductor devices 101a and 101b includes: a heat spreader 8U, 8L formed in a plate shape; a plurality of semiconductor elements 1 connected to a one-side surface of the heat spreader 8U, 8L; and one or a plurality of temperature detection elements 2. In the present embodiment, each of the semiconductor devices 101a and 101b includes: two semiconductor elements 1U, 1L; and one temperature detection element 2U, 2L. The number of the semiconductor elements 1 and the number of the temperature detection elements 2 are not limited thereto, and three semiconductor elements 1 and two temperature detection elements 2 may be included. The temperature detection element 2U, 2L is provided on the one-side surface of the heat spreader 8U, 8L or inside either of the semiconductor elements 1U, 1L. In the present embodiment, the temperature detection element 2U, 2L is provided on the one-side surface of the heat spreader 8U, 8L. Each of the temperature detection elements 2U and 2L includes two electrodes (not shown) and is connected to outside.

The semiconductor device 101a serving as an upper arm includes a first lead frame 3U and a second lead frame 4U which are main circuit wires. The semiconductor device 101b serving as a lower arm includes a first lead frame 3L and a second lead frame 4L which are main circuit wires. The first lead frames 3U and 3L and the second lead frames 4U and 4L are terminals regarding input and output for the U phase. The first lead frame 3U is electrically connected to a surface of each semiconductor element 1U that is on an opposite side to the heat spreader 8U side. The first lead frame 3L is electrically connected to a surface of each semiconductor element 1L that is on an opposite side to the heat spreader 8L side. The second lead frame 4U is electrically connected to the one-side surface of the heat spreader 8U. The second lead frame 4L is electrically connected to the one-side surface of the heat spreader 8L. A portion of the second lead frame 4U that is on an opposite side to a portion thereof connected to the heat spreader 8U, is exposed to outside from a sealing member 12 and connected to a P side which is an input side of the main circuit 100 of the inverter. A portion of the first lead frame 3L that is on an opposite side to a portion thereof connected to the semiconductor element 1L, is exposed to outside from a sealing member 12 and connected to an N side which is an input side of the main circuit 100 of the inverter. A portion of the first lead frame 3U that is on an opposite side to a portion thereof connected to the semiconductor element 1U, is exposed to outside from the sealing member 12 and connected to the U phase of the driven motor. A portion of the second lead frame 4L that is on an opposite side to a portion thereof connected to the heat spreader 8L, is exposed to outside from the sealing member 12 and connected to the U phase of the driven motor. The portions of the first lead frame 3U and the second lead frame 4L that are exposed to outside from the sealing members 12, are connected to each other.

The semiconductor device 101a serving as an upper arm includes a third lead frame 5U which is a control terminal, and the semiconductor device 101b serving as a lower arm includes a third lead frame 5L which is a control terminal. The third lead frame 5U is a terminal extending in a direction away from the heat spreader 8U in a state of being apart from the heat spreader 8U. The third lead frame 5U is electrically connected to one of the electrodes of the temperature detection element 2U via a first electric conductor 14U1. The third lead frame 5L is a terminal extending in a direction away from the heat spreader 8L in a state of being apart from the heat spreader 8L. The third lead frame 5L is electrically connected to one of the electrodes of the temperature detection element 2L via a first electric conductor 14L1. The other electrode of the temperature detection element 2U is electrically connected via a second electric conductor 14U2 to a monitoring terminal 3U1 extending from the first lead frame 3U. The other electrode of the temperature detection element 2L is electrically connected via a second electric conductor 14L2 to a monitoring terminal 3L1 extending from the first lead frame 3L. End portions of the third lead frames 5U and 5L and end portions of the monitoring terminals 3U1 and 3L1 are exposed to outside from the sealing members 12 and connected to a control circuit (not shown) of the inverter. Protection of the semiconductor elements 1U and 1L from overheating is performed on the basis of detected temperature information outputted to the control circuit. Each of the first lead frames 3U and 3L, the second lead frames 4U and 4L, and the third lead frames 5U and 5L is made of an electrically conductive metal such as copper or aluminum.

<Components of Semiconductor Device 101>

The components of each semiconductor device 101 will be described. Each upper arm and the corresponding lower arm have the same configuration, and thus description based on the semiconductor device 101a will be given. The two semiconductor elements 1U are connected in parallel. Each semiconductor element 1U is connected to the heat spreader 8U by means of a die-bonding material 6. The semiconductor element 1U is, for example, a metal oxide semiconductor field effect transistor (MOSFET), and the MOSFET has three types of electrodes, i.e., a gate electrode, a drain electrode, and a source electrode. An electrode of the MOSFET that is connected to the heat spreader 8U by means of the die-bonding material 6 is the drain electrode. An electrode of the MOSFET that is connected to the first lead frame 3U is the source electrode. The die-bonding material 6 is solder or Ag sinter. The semiconductor element 1U is formed on a semiconductor substrate made of silicon (Si) or a wide-bandgap semiconductor such as silicon carbide (SiC), gallium nitride (GaN), gallium oxide (GaO), or diamond. It is noted that the semiconductor element 1 may be an insulated gate bipolar transistor (IGBT). If the semiconductor element 1 is an IGBT, the IGBT has three types of electrodes, i.e., a gate electrode, a collector electrode, and an emitter electrode. The collector electrode corresponds to the drain electrode of the MOSFET, and the emitter electrode corresponds to the source electrode of the MOSFET.

The heat spreader 8U is an electrically conductive rectangular metal plate having excellent thermal conductivity and is made of, for example, copper. Copper is a material having excellent electrical conductivity and excellent thermal conductivity. The semiconductor element 1U and the temperature detection element 2U are provided on the one-side surface of the heat spreader 8U, and an insulation sheet 9 is provided on an other-side surface of the heat spreader 8U.

The temperature detection element 2U is, for example, a thermistor. The thermistor is an element having a resistance value that varies according to change in the temperature thereof. As shown in FIG. 4, the temperature detection element 2U includes: a temperature detection portion 2a which is an element body portion; two electrodes 2b provided to the temperature detection portion 2a so as to be located on the opposite side to the heat spreader 8U side; and a sealing material 2c sealing the temperature detection portion 2a in a state where portions of the two electrodes 2b that are on the opposite side to the heat spreader 8U side are exposed. The temperature detection portion 2a is thermally connected to the one-side surface of the heat spreader 8U via at least the sealing material 2c. This configuration makes it possible to thermally connect the temperature detection element 2U onto the heat spreader 8U easily. The semiconductor element 1U and the temperature detection element 2U are disposed on the heat spreader 8U, and the semiconductor element 1U and the temperature detection element 2U are thermally connected to each other via the heat spreader 8U. Thus, the thermal resistance between the semiconductor element 1U and the temperature detection element 2U is low, and it is possible to decrease a delay, in a response by the temperature detection element 2U, that occurs relative to increase in the temperature of the semiconductor element 1U due to heat generation. Since the delay in the response by the temperature detection element 2U can be decreased, the accuracy of detecting the temperature of the semiconductor element 1U can be improved.

Since the temperature detection portion 2a is sealed by the sealing material 2c, insulation between the temperature detection portion 2a and the outside is ensured. Thus, the heat spreader 8U and a joining portion 2d provided on an outer peripheral portion of the sealing material 2c can be joined together by means of a joining material 7. The joining portion 2d is made of metal. The joining material 7 is, for example, solder or Ag sinter. In the case where the temperature detection portion 2a of the temperature detection element 2U is not sealed, a joining material 7 having insulation properties is used. It is noted that the number of the electrodes 2b of the temperature detection element 2U is not limited to two. The number of the electrodes 2b of the temperature detection element 2U only has to be at least two, and the electrodes 2b may be provided at any location on the temperature detection portion 2a. Further, the temperature detection element 2U may be a diode.

One of the electrodes 2b of the temperature detection element 2U is connected to the third lead frame 5U via the first electric conductor 14U1, and the other electrode 2b of the temperature detection element 2U is connected to the monitoring terminal 3U1 via the second electric conductor 14U2. The first and second electric conductors 14U1 and 14U2 are, for example, bonding wires. If bonding wires are used as wires, the degree of freedom in wiring is improved so that space saving can be attained. However, the temperature detection element 2U is very small, and the electrodes 2b to which the bonding wires are connected are also small, and thus defective connection between each bonding wire and the corresponding electrode 2b might occur. Considering this, in order to ameliorate the defective connection, a region for the connection may be enlarged, and thin metal plates may be used, instead of the bonding wires, as wires. An arrangement region of the temperature detection element 2U will be described later.

A metal plate 10 is thermally connected via the insulation sheet 9 to the other-side surface of the heat spreader 8U. The metal plate 10 is made of, for example, copper or aluminum. The insulation sheet 9 is made of, for example, a ceramic resin material having insulation properties.

The heat spreader 8U, the two semiconductor elements 1U, the temperature detection element 2U, the first lead frame 3U, the second lead frame 4U, the third lead frame 5U, the insulation sheet 9, and the metal plate 10 are sealed by the sealing member 12. The portion of the first lead frame 3U that is on the opposite side to the portion thereof connected to each semiconductor element 1U, the portion of the second lead frame 4U that is on the opposite side to the portion thereof connected to the heat spreader 8U, the portion of the third lead frame 5U that is on the opposite side to the portion thereof connected to the first electric conductor 14U1, and a surface of the metal plate 10 that is on an opposite side to a surface thereof connected to the insulation sheet 9, are exposed from the sealing member 12. The sealing member 12 is made of, for example, mold resin. This configuration makes it possible to easily form a semiconductor device having a 2-in-1 or 6-in-1 structure. Further, the semiconductor device having the 2-in-1 or 6-in-1 structure can be downsized.

A configuration obtained through the sealing by the sealing member 12 is the configuration of the semiconductor device 101a. The metal plate 10 and the inside of the semiconductor device 101a including the semiconductor element 1U and the like, are insulated from each other by the insulation sheet 9. Heat generated inside the semiconductor device 101a is dissipated from the surface of the metal plate 10 that is on the opposite side to the surface thereof connected to the insulation sheet 9. In order to promote the heat dissipation and cool the inside of the semiconductor device 101a, the semiconductor device 101a may be further provided with a cooler 13. The cooler 13 is thermally connected to the metal plate 10 via a joining layer 11. Since the cooler 13 is thermally connected to the metal plate 10, the cooler 13 is thermally connected to the other-side surface of the heat spreader 8U. Likewise, the cooler 13 is thermally connected to an other-side surface of the heat spreader 8L. The joining layer 11 is made of, for example, solder. The cooler 13 includes cooling fins (not shown) on the inner surface thereof. The cooler 13 is formed as, for example, a die casting of a metal such as an aluminum alloy or a copper alloy. The cooler 13 has a flow path (not shown) through which a coolant flows from the heat spreader 8U side to the heat spreader 8L side. The direction of each arrow shown in FIG. 3 is a coolant-flowing direction 15. The coolant flows in an orientation in which the upper arm side is defined as an upstream side and the lower arm side is defined as a downstream side. The orientation in which the coolant flows is not limited thereto, and may be such that the upper arm side is defined as the downstream side and the lower arm side is defined as the upstream side.

<Arrangement Region of Temperature Detection Element 2U>

An arrangement region of the temperature detection element 2U which is a major part of the present disclosure will be described with reference to FIG. 5. Although an arrangement region of the temperature detection element 2U will be described, the same applies also to the temperature detection element 2L. FIG. 5 is a plan view showing the two semiconductor elements 1U, the one temperature detection element 2U, and the heat spreader 8U of the semiconductor device 101a. In FIG. 5, the electrodes of each semiconductor element 1U and the temperature detection element 2U are not shown. A line segment connecting the centers of the two respective adjacent semiconductor elements 1U is defined as X. A straight line that passes through one of the centers of the two adjacent semiconductor elements 1U and that is perpendicular to X and parallel to the one-side surface of the heat spreader 8U is defined as Y1. A straight line that passes through the other one of the centers of the two adjacent semiconductor elements 1U and that is perpendicular to X and parallel to the one-side surface of the heat spreader 8U is defined as Y2. At least a part of the temperature detection element 2U is located in an arrangement region interposed between Y1 and Y2, as seen in a direction perpendicular to the one-side surface of the heat spreader 8U. In FIG. 5, a region delimited by a broken line is the arrangement region. The number of the temperature detection elements 2U is smaller than the number of the semiconductor elements 1U.

Since at least a part of the temperature detection element 2U is located in such an arrangement region, the one temperature detection element 2U can accurately detect the temperatures of at least two semiconductor elements 1U. Consequently, the one temperature detection element 2U enables the at least two semiconductor elements 1U to be protected from overheating. Therefore, the number of the temperature detection elements 2U can be decreased. Since the number of the temperature detection elements 2U can be decreased, the semiconductor device 101a can be downsized. Even if the number of the semiconductor elements 1U composing the semiconductor device 101a is two or more, the number of the temperature detection elements 2U can be made smaller than the number of the semiconductor elements, and thus the number of the control terminals for outputting detected information from the temperature detection elements 2U to outside, and a space for wiring from each temperature detection element 2U, can be decreased. Since the number of the control terminals and the space for the wiring are decreased, the semiconductor device 101a can be downsized.

In the arrangement region, a position at which the detection accuracy of the temperature detection element 2U is highest is a position that is located at the midpoint of X and that is apart from the semiconductor elements 1U by the same distance. This is because the position is at a shortest distance from each semiconductor element 1U. However, there is variation in characteristics among the semiconductor elements 1U, and thus there is variation also in heat generation among the semiconductor elements 1U. Thus, the temperature detection element 2U is mounted at a position also in consideration of the variation in characteristics among the semiconductor elements 1U. FIG. 5 shows an example in which the temperature detection element 2U is disposed at a position at which the detection accuracy thereof is highest, in consideration of the variation in characteristics among the semiconductor elements 1U and characteristics of the temperature detection element 2U.

As described above, the semiconductor device 101a according to the first embodiment includes: the heat spreader 8U formed in a plate shape; the two semiconductor elements 1U connected to the one-side surface of the heat spreader 8U; and the one temperature detection element 2U. The temperature detection element 2U is provided on the one-side surface of the heat spreader 8U. If a line segment connecting the centers of the two respective adjacent semiconductor elements 1U is defined as X, a straight line that passes through one of the centers of the two adjacent semiconductor elements 1U and that is perpendicular to X and parallel to the one-side surface of the heat spreader 8U is defined as Y1, and a straight line that passes through the other one of the centers of the two adjacent semiconductor elements 1U and that is perpendicular to X and parallel to the one-side surface of the heat spreader 8U is defined as Y2, at least a part of the temperature detection element 2U is located in the arrangement region interposed between Y1 and Y2, as seen in the direction perpendicular to the one-side surface of the heat spreader. Consequently, since each semiconductor element 1U and the temperature detection element 2U are disposed on the heat spreader 8U, and the semiconductor element 1U and the temperature detection element 2U are thermally connected to each other via the heat spreader 8U, the thermal resistance between the semiconductor element 1U and the temperature detection element 2U is low, and it is possible to decrease a delay, in a response by the temperature detection element 2U, that occurs relative to increase in the temperature of the semiconductor element 1U due to heat generation. Therefore, the accuracy of detecting the temperature of the semiconductor element 1U can be improved. In addition, the one temperature detection element 2U can accurately detect the temperatures of at least two semiconductor elements 1U, and thus the one temperature detection element 2U enables the at least two semiconductor elements 1U to be protected from overheating. Therefore, the number of the temperature detection elements 2U can be decreased, whereby the semiconductor device 101a can be downsized.

If the number of the temperature detection elements 2U is smaller than the number of the semiconductor elements 1U, the number of the control terminals for outputting detected information from the temperature detection elements 2U to outside, and the space for the wiring from each temperature detection element 2U, can be decreased. Therefore, the semiconductor device 101a can be downsized. If the temperature detection element 2U is provided on the one-side surface of the heat spreader 8U, and the temperature detection portion 2a of the temperature detection element 2U is thermally connected to the one-side surface of the heat spreader 8U via at least the sealing material 2c, the temperature detection element 2U can be thermally connected onto the heat spreader 8U easily.

If the heat spreader 8U, the plurality of semiconductor elements 1U, the temperature detection element 2U, the first lead frame 3U, the second lead frame 4U, the third lead frame 5U, the insulation sheet 9, and the metal plate 10 are sealed by the sealing member 12, a semiconductor device having a 2-in-1 or 6-in-1 structure can be easily formed. Further, the semiconductor device having the 2-in-1 or 6-in-1 structure can be downsized.

### Second Embodiment

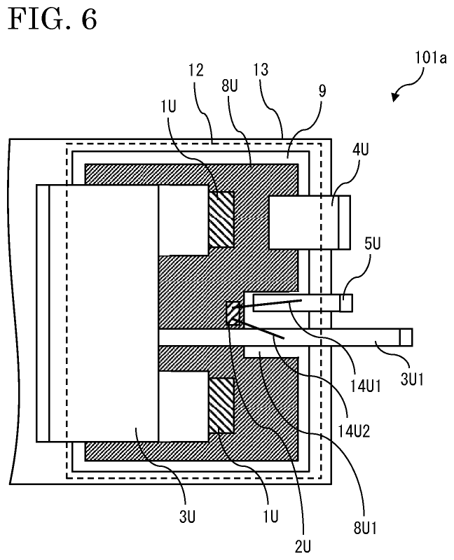

A semiconductor device 101a according to a second embodiment will be described. FIG. 6 is a plan view schematically showing a configuration of the semiconductor device 101a according to the second embodiment, and is a diagram in which the sealing member 12 has been excluded. A broken line shown in FIG. 6 indicates the external shape of the sealing member 12. The semiconductor device 101a according to the second embodiment has a configuration in which a cut 8U1 is formed in the heat spreader 8U.

The cut 8U1 is formed in the outer peripheral portion of the heat spreader 8U. The cut 8U1 is a portion formed by cutting the heat spreader 8U from the outer periphery thereof to the inside thereof. Although the cut 8U1 is formed in a rectangular shape in the present embodiment, the shape of the cut 8U1 is not limited thereto, and the cut 8U1 may be a portion delimited by a curved line. In the case of making the heat spreader 8U through press working, the cut 8U1 can be simultaneously formed at the time of the press working. The cut 8U1 may be formed by, after the heat spreader 8U is made, eliminating a part of the heat spreader 8U through cutting or the like.

As seen in the direction perpendicular to the one-side surface of the heat spreader 8U, a portion of the third lead frame 5U that is on the heat spreader 8U side overlaps with a region in which the cut 8U1 is formed. With this configuration, the third lead frame 5U can be disposed inward of an outer periphery, of the heat spreader, that does not have any cut 8U1. Thus, the semiconductor device 101a can be downsized in a direction in which the third lead frame 5U extends.

As seen in the direction perpendicular to the one-side surface of the heat spreader 8U, the two adjacent semiconductor elements 1U are disposed apart from each other in regions on both sides between which the cut 8U1 is interposed, and the temperature detection element 2U is disposed adjacently to the cut 8U1. Heat generated from each semiconductor element 1U is likely to concentrate at a region, of the heat spreader 8U, that has been narrowed owing to cutting. If the temperature detection element 2U is disposed in the region, of the heat spreader 8U, that has been narrowed owing to the cutting in this manner, the responsiveness of the temperature detection element 2U can be improved. Since the responsiveness of the temperature detection element 2U is improved, the accuracy of detecting the temperature of the semiconductor element 1U can be improved.

### Third Embodiment

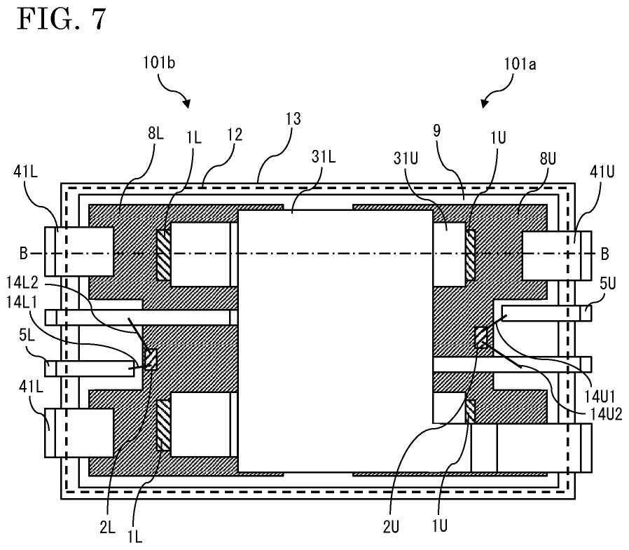

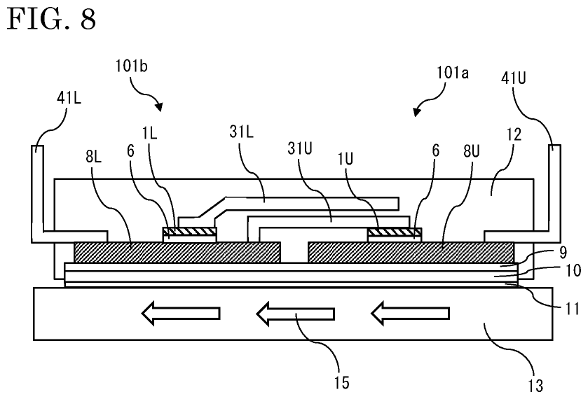

Semiconductor devices 101 according to a third embodiment will be described. FIG. 7 is a plan view schematically showing configurations of semiconductor devices 101a and 101b according to the third embodiment. FIG. 8 is a cross-sectional view schematically showing the semiconductor devices 101a and 101b, taken at a cross-sectional position B-B in FIG. 7. In FIG. 7, a sealing member 12 has been excluded, and a broken line indicates the external shape of the sealing member 12. In the semiconductor devices 101 according to the third embodiment, configurations of first lead frames 31U and 31L and a second lead frame 41L which are main circuit wires, and a configuration of the sealing member 12, are different from those in the first embodiment.

The configurations of the first lead frames 31U and 31L and second lead frames 41U and 41L will be described. The first lead frame 31U has one end connected to each semiconductor element 1U composing the semiconductor device 101a serving as an upper arm. Another end of the first lead frame 31U is connected to the one-side surface of the heat spreader 8L of the semiconductor device 101b. The second lead frame 41U has one end electrically connected to the one-side surface of the heat spreader 8U. Another end of the second lead frame 41U is connected to the P side which is an input side of the main circuit 100 of the inverter. The first lead frame 31L has one end connected to each semiconductor element 1L composing the semiconductor device 101b serving as a lower arm. Another end of the first lead frame 31L is connected to the N side which is an input side of the main circuit 100 of the inverter. The second lead frame 41L has one end electrically connected to the one-side surface of the heat spreader 8L. Another end of the second lead frame 41L is connected to the U phase of the driven motor.

As shown in FIG. 8, the first lead frame 31U and the first lead frame 31L are disposed apart from each other so as to overlap while being kept parallel to each other. Directions of currents that respectively flow in the first lead frame 31U and the first lead frame 31L, are opposite to each other. Thus, directions of magnetic fields generated owing to the currents are also opposite to each other, and the magnetic fields cancel each other. Therefore, an inductance can be decreased.

The configuration of the sealing member 12 will be described. In the present embodiment, the semiconductor devices 101a and 101b serving as the upper and lower arms for the U phase are sealed together by the sealing member 12. Since the first lead frames 31U and 31L and the second lead frame 41L have the above configurations, the semiconductor devices 101a and 101b can be sealed together by the sealing member 12. Further, the heat spreaders 8U and 8L are thermally connected to one metal plate 10 without providing the metal plates 10 respectively to the heat spreaders 8U and 8L.

If the semiconductor devices 101a and 101b are sealed together by the sealing member 12, the upper and lower arms can be more easily connected to each other than in the configuration described in the first embodiment in which each arm is separately sealed. In addition, the semiconductor devices 101a and 101b can be disposed close to each other. Thus, the lengths of the terminals to which the upper and lower arms are connected can be shortened, and the semiconductor devices 101a and 101b serving as the upper and lower arms can be downsized.

In general, the structure in which each arm for the U phase is separately sealed as in the first embodiment, is called a 1-in-1 structure, and the structure in which the upper and lower arms for the U phase are sealed together as in the third embodiment, is called a 2-in-1 structure. A 4-in-1 structure and a 6-in-1 structure can be easily constructed on the basis of the 2-in-1 structure described in the third embodiment. In the main circuit 100 of the inverter in the present disclosure, any of the structures may be used. By using the structure in which the arms for each phase are sealed together, the number of the terminals is decreased, whereby the inverter can be downsized.

### Fourth Embodiment

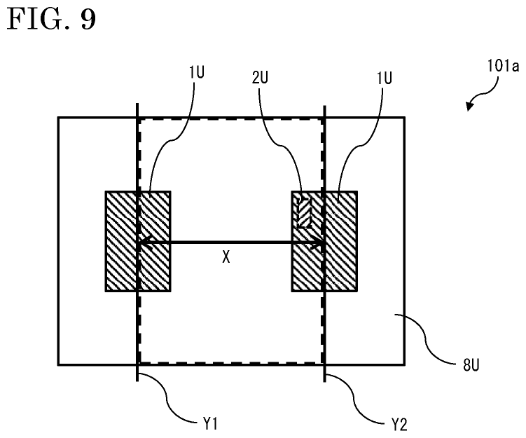

A semiconductor device 101a according to a fourth embodiment will be described. FIG. 9 is a plan view showing a major part of the semiconductor device 101a according to the fourth embodiment, and is a plan view showing the two semiconductor elements 1U, the one temperature detection element 2U, and the heat spreader 8U of the semiconductor device 101a. In FIG. 9, the electrodes of the semiconductor elements 1U and the temperature detection element 2U are not shown. The semiconductor device 101a according to the fourth embodiment has a configuration in which the temperature detection element 2U is provided inside either of the semiconductor elements 1U.

The temperature detection element 2U is provided inside one or another one of the two adjacent semiconductor elements 1U. In FIG. 9, the temperature detection element 2U is provided inside the semiconductor element 1U disposed on the right side. Since the temperature detection element 2U is provided inside the semiconductor element 1U, the external shape of the temperature detection element 2U is indicated by a broken line. The temperature detection element 2U is a diode. With this configuration, the semiconductor element 1U and the temperature detection element 2U are thermally connected to each other inside the semiconductor element 1U. Thus, the thermal resistance between the semiconductor element 1U and the temperature detection element 2U is low, and it is possible to decrease a delay, in a response by the temperature detection element 2U, that occurs relative to increase in the temperature of the semiconductor element 1U due to heat generation. Since the delay in the response by the temperature detection element 2U can be decreased, the accuracy of detecting the temperature of the semiconductor element 1U can be improved.

In addition, the temperature detection element 2U is connected to the source electrode inside the semiconductor element 1U, and thus the number of wires of the temperature detection element 2U is one, and the one wire is connected to the third lead frame 5U. Since the number of the wires of the temperature detection element 2U is one, the space for the wiring is decreased as compared to the case where the temperature detection element 2U is provided outside of the semiconductor element 1U. Thus, further space saving can be attained, whereby the semiconductor device 101a can be further downsized.

If the temperature detection element 2U is provided inside the semiconductor element 1U, the interval between the two adjacent semiconductor elements 1U is desirably a shortest interval that enables insulation between both semiconductor elements 1U to be ensured. If the two adjacent semiconductor elements 1U are disposed such that the interval between the two adjacent semiconductor elements 1U becomes shortest while the interval is kept as a distance that enables the insulation to be ensured, it is possible to protect both semiconductor elements 1U from overheating while maintaining the accuracy of detecting the temperatures of both semiconductor elements 1U, even in the case of embedding the temperature detection element 2U in one of the semiconductor elements 1U.

### Fifth Embodiment

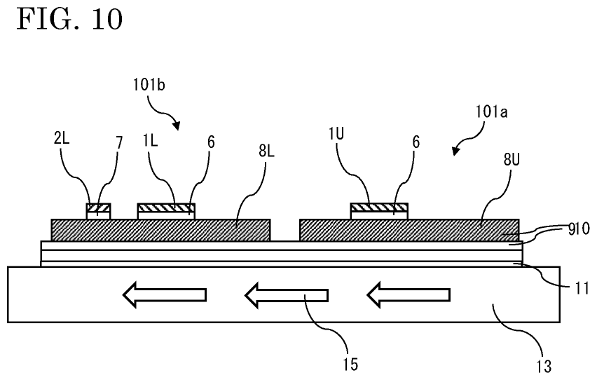

Semiconductor devices 101 according to a fifth embodiment will be described. FIG. 10 is a side view schematically showing configurations of the semiconductor devices 101 according to the fifth embodiment. In FIG. 10, the sealing member 12 has been excluded, and the lead frames are not shown. The semiconductor devices 101 according to the fifth embodiment have a configuration in which the temperature detection element 2U is not provided and only the temperature detection element 2L is provided. The arrangement of the semiconductor elements 1 is the same as that in FIG. 2 described in the first embodiment.

The semiconductor devices 101 are provided with the cooler 13. The semiconductor devices 101 include two sets. Each set is composed of: the heat spreader; and the plurality of semiconductor elements connected to the one-side surface of the heat spreader. The two sets in the present embodiment are the semiconductor device 101a and the semiconductor device 101b. The semiconductor device 101a is defined as a first set, and the semiconductor device 101b is defined as a second set. The cooler 13 is thermally connected to the other-side surfaces of the heat spreaders 8U and 8L of the respective sets. In the present embodiment, the heat spreaders 8U and 8L and the metal plate 10 are thermally connected to each other via the insulation sheet 9, and the metal plate 10 and the cooler 13 are thermally connected to each other via the joining layer 11. The cooler 13 has a flow path (not shown) through which the coolant flows from the heat spreader 8U side in the first set to the heat spreader 8L side in the second set. The direction of each arrow shown in FIG. 10 is the coolant-flowing direction 15. The coolant flows in an orientation in which the upper arm side is defined as an upstream side and the lower arm side is defined as a downstream side.

The temperature detection element 2 is provided at least on the one-side surface of the heat spreader 8L of the second set or inside either of the semiconductor elements 1L connected to the one-side surface of the heat spreader 8L of the second set. In the present embodiment, the temperature detection element 2L is provided on the one-side surface of the heat spreader 8L of the second set. The temperature detection element 2U is provided neither on the one-side surface of the heat spreader 8U of the first set nor inside either of the semiconductor elements 1U connected to the one-side surface of the heat spreader 8U of the first set.

If the coolant flowing through the cooler 13 flows in an orientation in which the upper arm side is defined as the upstream side and the lower arm side is defined as the downstream side, the coolant is warmed by heat generated from the semiconductor device 101a, and then the semiconductor device 101b is cooled by the warmed coolant. Thus, the semiconductor elements 1L composing the semiconductor device 101b on the downstream side are more likely to have high temperatures than the semiconductor elements 1U composing the semiconductor device 101a on the upstream side. Considering this, at least the temperature detection element 2L is provided on the one-side surface of the heat spreader 8L of the second set so that protection from overheating is performed on the semiconductor elements 1L which are more likely to have high temperatures. Consequently, the semiconductor elements 1U of the semiconductor device 101a on the upstream side can also be protected. In addition, if the temperature detection element 2U is provided neither on the one-side surface of the heat spreader 8U of the first set nor inside either of the semiconductor elements 1U connected to the one-side surface of the heat spreader of the first set, the number of the temperature detection elements can be decreased. Thus, the number of the control terminals can be decreased, whereby the semiconductor devices can be downsized.

The arrangement of the temperature detection element 2L will be further described. The temperature detection element 2L provided on the one-side surface of the heat spreader 8L of the second set or inside either of the semiconductor elements 1L connected to the one-side surface of the heat spreader 8L of the second set, is disposed in a region that is closer to the downstream side for the coolant than X in the arrangement region is. The temperature on the downstream side of the semiconductor elements 1L composing the semiconductor device 101b on the downstream side is more likely to become high than the temperature on the upstream side of the semiconductor elements 1L. This is because, on the downstream side of the semiconductor elements 1L, the coolant has passed through the semiconductor elements 1L having generated heat, so that the temperature of the coolant has increased. Considering this, the temperature detection element 2L is provided in the region that is closer to the downstream side for the coolant than X in the arrangement region is, whereby protection from overheating is performed on the downstream side, of the semiconductor elements 1L, on which the temperature is likely to become high. Consequently, the semiconductor elements 1L can be assuredly protected from overheating.

As described above, in the semiconductor devices 101 according to the fifth embodiment, the cooler 13 has the flow path through which the coolant flows from the heat spreader 8U side in the first set to the heat spreader 8L side in the second set, and the temperature detection element 2 is provided at least on the one-side surface of the heat spreader 8L of the second set or inside either of the semiconductor elements 1L connected to the one-side surface of the heat spreader 8L of the second set. Consequently, protection from overheating is performed on the semiconductor elements 1L which are more likely to have high temperatures. Thus, the semiconductor elements 1U of the semiconductor device 101a on the upstream side can also be protected.

If the temperature detection element 2U is provided neither on the one-side surface of the heat spreader 8U of the first set nor inside either of the semiconductor elements 1U connected to the one-side surface of the heat spreader of the first set, the number of the temperature detection elements can be decreased. Thus, the number of the control terminals can be decreased, whereby the semiconductor devices can be downsized. In addition, the temperature on the downstream side of the semiconductor elements 1L composing the semiconductor device 101b on the downstream side is more likely to become high than the temperature on the upstream side of the semiconductor elements 1L. Thus, if the temperature detection element 2L is disposed in the region that is closer to the downstream side for the coolant than X in the arrangement region is, protection from overheating is performed on the downstream side, of the semiconductor elements 1L, on which the temperature is likely to become high. Consequently, the semiconductor elements 1L can be assuredly protected from overheating.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1, 1U, 1L semiconductor element
2, 2U, 2L temperature detection element
2a temperature detection portion
2b electrode
2c sealing material
2d joining portion
3U, 3L, 31U, 31L first lead frame
3U1 monitoring terminal
3L1 monitoring terminal
4U, 4L, 41U, 41L second lead frame
5U, 5L third lead frame
6 die-bonding material
7 joining material
8U, 8L heat spreader
8U1 cut
9 insulation sheet
10 metal plate
11 joining layer
12 sealing member
13 cooler
14U1 first electric conductor
14U2 second electric conductor
14L1 first electric conductor
14L2 second electric conductor
15 coolant-flowing direction
100 main circuit of inverter
101 semiconductor device

What is claimed is:

1. A semiconductor device comprising:
a heat spreader formed in a plate shape;
a plurality of semiconductor elements connected to a one-side surface of the heat spreader; and
one or a plurality of temperature detection elements, wherein
each temperature detection element is provided on the one-side surface of the heat spreader or inside any of the semiconductor elements, and
if
a line segment connecting centers of two respective adjacent ones of the semiconductor elements is defined as X,
a straight line that passes through one of the centers of the two adjacent semiconductor elements and that is perpendicular to the line segment X and parallel to the one-side surface of the heat spreader is defined as Y1, and
a straight line that passes through another one of the centers of the two adjacent semiconductor elements and that is perpendicular to the line segment X and parallel to the one-side surface of the heat spreader is defined as Y2,
at least a part of the temperature detection element is located in an arrangement region interposed between the straight line Y1 and the straight line Y2, as seen in a direction perpendicular to the one-side surface of the heat spreader.

2. The semiconductor device according to claim 1, wherein the number of the temperature detection elements is smaller than the number of the semiconductor elements.

3. The semiconductor device according to claim 1, wherein
each temperature detection element is provided on the one-side surface of the heat spreader,
the temperature detection element includes
an element body portion,
two electrodes provided to the element body portion so as to be located on an opposite side to the heat spreader side, and
a sealing material sealing the element body portion in a state where portions of two the electrodes that are on the opposite side to the heat spreader side are exposed, and
the element body portion is thermally connected to the one-side surface of the heat spreader via at least the sealing material.

4. The semiconductor device according to claim 1, wherein
each temperature detection element is provided inside one or another one of the two adjacent semiconductor elements, and
an interval between the two adjacent semiconductor elements is a shortest interval that enables insulation between both semiconductor elements to be ensured.

5. The semiconductor device according to claim 3, further comprising:
a first lead frame electrically connected to surfaces of the plurality of semiconductor elements that are on the opposite side to the heat spreader side;
a second lead frame electrically connected to the one-side surface of the heat spreader;
a third lead frame which is a terminal extending in a direction away from the heat spreader in a state of being apart from the heat spreader, the third lead frame being electrically connected to one of the electrodes of the temperature detection element via a first electric conductor; and
a metal plate thermally connected to an other-side surface of the heat spreader via an insulation sheet, wherein
another one of the electrodes of the temperature detection element is electrically connected to the first lead frame via a second electric conductor, and
the heat spreader, the plurality of semiconductor elements, the temperature detection element, the first lead frame, the second lead frame, the third lead frame, the insulation sheet, and the metal plate are sealed by a sealing member such that a portion of the first lead frame that is on an opposite side to a portion thereof connected to each semiconductor element, a portion of the second lead frame that is on an opposite side to a portion thereof connected to the heat spreader, a portion of the third lead frame that is on an opposite side to a portion thereof connected to the first electric conductor, and a surface of the metal plate that is on an opposite side to a surface thereof connected to the insulation sheet, are exposed.

6. The semiconductor device according to claim 1, further comprising a cooler, wherein
two sets are provided, each set being composed of
the heat spreader and
the plurality of semiconductor elements connected to the one-side surface of the heat spreader,
the cooler is thermally connected to other-side surfaces of the heat spreaders of the respective sets, and has a flow path through which a coolant flows from the heat spreader side in a first one of the sets to the heat spreader side in a second one of the sets, and
each temperature detection element is provided at least on the one-side surface of the heat spreader of the second set or inside any of the semiconductor elements connected to the one-side surface of the heat spreader of the second set.

7. The semiconductor device according to claim 6, wherein the temperature detection element is provided neither on the one-side surface of the heat spreader of the first set nor inside any of the semiconductor elements connected to the one-side surface of the heat spreader of the first set.

8. The semiconductor device according to claim 6, wherein the temperature detection element provided on the one-side surface of the heat spreader of the second set or inside the semiconductor element connected to the one-side surface of the heat spreader of the second set, is disposed in a region that is closer to a downstream side for the coolant than the line segment X in the arrangement region is.

9. The semiconductor device according to claim 5, wherein
a cut is formed in an outer peripheral portion of the heat spreader, and
as seen in the direction perpendicular to the one-side surface of the heat spreader,
a portion of the third lead frame that is on the heat spreader side overlaps with a region in which the cut is formed,
the two adjacent semiconductor elements are disposed apart from each other in regions on both sides between which the cut is interposed, and
the temperature detection element is disposed adjacently to the cut.
